(19) United States
(12) Patent Application Publication
(10) Pub. No.: US 2004/0118349 A1
(43) Pub. Date: Jun. 24, 2004

(54) Vapor deposition shield for optical fibers

(75) Inventors: James P. Endle, Austin, TX (US); Martin G. Afflerbaugh, Austin, TX (US)

Correspondence Address: WESTERMAN, HATTORI, DANIELS & ADRIAN, LLP, 1250 CONNECTICUT AVENUE, NW, SUITE 700, WASHINGTON, DC, 20036, US

(73) Assignee: 3M Innovative Properties Company

(21) Appl. No.: 10/325,583

(22) Filed: Dec. 19, 2002

(51) Int. Cl. C23C 16/00; C25B 9/00; B25B 1/20; C25B 11/00

(52) U.S. Cl. 118/728; 204/298.15; 269/37

(57) ABSTRACT

An organizing fixture provides space for a number of frame carriers used for releasable mounting of a number of filament-positioning frames. Each filament-positioning frame holds a filamentary coil and a plurality of filaments formed into a parallel array of filaments, extending from the filamentary coil. A frame carrier includes a divider wall on which filament-positioning frames may be mounted so that parallel arrays of filaments extend over the upper edge of each divider wall. Organizing fixtures accommodate several layers of frame carriers that produce a stack of divider walls having gaps between layers through which filament ends protrude in a suitable position for application of condensable materials using vacuum deposition techniques.

### FIELD OF THE INVENTION

The invention relates to protective packaging of filamentary material to prevent damage during transit and more particularly to an apparatus for a plurality of filament organizing frames to precisely position bare filament termini adjacent to equipment used for controlled deposition of condensable vapor on the surfaces of bare filaments.

### BACKGROUND OF THE INVENTION

Glass has been used for centuries as a material for controlling and modifying the properties of light beams. A recent and rapidly expanding application of the light modifying properties of glass structures involves the drawing of fine filaments of highly purified glass, more commonly referred to as optical fibers, that direct light signals between light transmitting and receiving locations. The use of optical fiber communication networks has grown to provide an alternative to coaxial cable systems. Advantages provided by optical fiber communications networks include lower cost, the use of fewer signal repeaters for correcting signal distortion, and a higher signal carrying capacity than coaxial cable networks.

Interconnection of fiber optic networks requires high precision devices in the form of optical connectors that join optical fibers to peripheral equipment and other optical fibers while maintaining adequate signal strength. In operation, an optical connector centers the small fiber so that the light gathering core lies directly over and in alignment with a light transmitting source or another fiber. Following correct positioning of an optical fiber, known connecting structures such as crimped connections, soldered connections, spliced connections and the like may be used to maintain alignment between sections of optical fiber.

Soldered connections, in the form of optical fiber splices, terminations and hermetic seals, may include a thin metallic layer over the surface of an optical fiber adjacent to the position at which the splice, termination or seal will be made. Metal coating of terminal ends of optical fibers facilitates solder bonding of connectors before connection of one optical fiber to another optical fiber or related device.

U.S. Pat. No. 4,033,668 describes a method for joining a first glass member, such as an optical fiber, to a second member by means of solderable splices and terminations, which additionally can form hermetic seals. The splice, termination or seal may be formed after coating the peripheral surface of the glass member with a thin adhering metallic layer. After properly positioning the coated glass member, formation of a splice termination or seal with a corresponding member, may use heated solder to flow around the joint to form a bond between the members when cooled. When the second member is also formed of glass, a thin adhering metallic layer, similarly formed on the peripheral surface thereof, provides a solder receptive surface in the area of the intended joint. Metal may be applied to terminal portions of e.g. optical fibers by dipping them into a paste containing conductive metal particles.

U.S. Pat. No. 5,100,507 addresses finishing techniques for lensed optical fibers. The process of finishing an optical fiber places an integral lens and a metallized outer coating on the end of an optical fiber. Metal may be deposited on the ends of optical fibers using known sputtering techniques. Materials deposited in this way include titanium, platinum and gold. Application of metal close to the lensed end of an optical fiber allows the formation of a soldered connection very close to the tip of the fiber. This limits subsequent movement of a lensed fiber relative to an aligned optical device.

Prior description of soldered connections involves individual processing of metallized ends of optical fibers. Optical fiber handling represents a challenge for the optical fiber industry. Manufacturing operations may include a number of steps requiring handling of long and short lengths of optical fiber. These lengths of optical fiber are fragile filaments requiring careful handling using more efficient processes to accelerate the production of optical fibers for communication links and related devices. With a growing demand for optical fiber systems and devices, there is a need for processing a plurality of optical fibers simultaneously.

Accompanying the need for simultaneously processing a large number of individual components is the trend towards concentration of manufacturing operations to take advantage of specialist capabilities. This trend necessitates transferal of components, representing work in progress, between manufacturing sites. Such transfer of work in progress may only be possible using transportation equipment that not only contains but also protects partially completed components from damage, particularly when the contents of a container include fragile structures such as optical fibers. For convenient processing, there is a need for a transportation container to organize multiple optical fibers to facilitate component treatment for device manufacture.

### SUMMARY OF THE INVENTION

The present invention provides a filament organizing apparatus, including frame carriers and filament positioning frames designed to organize a large number of optical fibers having their tips exposed to receive a coating of selected materials, such as metals, oxides, and organic coatings, that may be applied using vapor deposition techniques. A preferred process for depositing material on tips, particularly end faces, of optical fibers uses equipment of the type described in U.S. Pat. No. 5,849,162. The process is a reactive sputtering process using equipment including a reduced pressure chamber operating between 10⁻⁴ and 10⁻² torr and means for transporting substrates, such as terminal portions of optical fibers, past a coating station. Transportation means include a rotating structure the holds substrates as they pass a coating station comprising a magnetron sputtering device and an elongated plasma generator. During deposition of material, the plasma generated by the sputtering target and the plasma generator interdiffuse so as to form one continuous activating and sputtering plasma. For this purpose, the sputtering target and elongated plasma generator occupy positions that are spatially and atmospherically contiguous. Equipment of the type described previously may be used to deposit multiple layers of material by movement of substrates through coating zones past sputtering targets of differing chemical composition.

An apparatus according to the present invention is vacuum compatible for direct attachment to vapor deposition equipment to precisely position bare fiber tips, also referred to herein as bare filament termini, adjacent to vacuum deposition sources. The portion of a filament organizing apparatus exposed to vacuum deposition coating equipment comprises a face plate including at least a first divider wall having placed thereon at least a second divider wall to provide an interface between the first divider wall and the second divider wall. The interface includes an elongated structured slot formed of a plurality of openings in a common plane. Each of the plurality of openings has an entry into a cavity formed between the first divider wall and the second divider wall. The cavity is occupied by an optical fiber having coaxial alignment therewith. The optical fiber includes a boundary between a bare terminal portion and a buffered portion such that the boundary is positioned in the cavity so that a section of the bare terminal portion may either be coplanar with or protrude from the entry in front of the faceplate for deposition of condensable material thereon. The entry of each of the plurality of openings has a size to substantially prevent deposit of condensable material from reaching the boundary inside the cavity. Using an aspect ratio, of the entry size of each opening and the location of the boundary between the bare terminal portion and the buffered portion of the optical fiber, it is possible to control diffusion of condensable material into the optical fiber-containing cavity. Aspect ratios between about 1:1 and 1:4, preferably about 1:2, substantially prevent material deposit in the boundary region. Material deposition preferably involves substrate rotation by several plasma coating stations required to form a multi-layer vapor-deposited coating structure, comprising alternating layers of silicon and tantalum oxides, that concentrates over the end surface of an optical fiber.

Construction of an apparatus according to the present invention requires assembly of components including an organizing fixture, one or more frame carriers, that mount on the organizing fixture, and filament-positioning frames that couple to frame carriers. An organizing fixture includes a fixture base having a central rod between a first pair of positioning rods and a second pair of positioning rods. Frame carriers each include a divider wall having a first end opposite a second end, a front side opposite a rear side and an upper edge opposite a lower edge. The first end fits between the first pair of positioning rods, and the second end fits between the second pair of positioning rods such that a portion of the divider wall, between the first end and the second end, lies adjacent to the central rod. The lower edge of the first divider wall, mounted on the organizing fixture, makes contact with the fixture base. Each frame carrier includes at least one reference plate attached to the rear side of the divider wall. The reference plate has a plurality of pin locators projecting from its upper surface.

An organizing fixture has space for a number of frame carriers each capable of holding two filament-positioning frames. Each filament-positioning frame holds a filamentary coil and a plurality of filaments extending from the coil and formed into a parallel array of filaments. The filament-positioning frame comprises a coil carrier that includes an elongate plate having a first end opposite a second end. A coil retainer, attached to the coil carrier at the first end, includes a fastener end to attach the coil retainer to the coil carrier. Also, the coil retainer includes a clasp end to restrict movement of the filamentary coil at the first end of the coil carrier. A clamp base, attached at the second end of the coil carrier, includes a substantially rectangular base-plate having a lower surface and an upper surface. The lower surface of the base-plate contacts the coil carrier. The base-plate further includes alignment projections at the perimeter of the upper surface and a pair of threaded holes adjacent to a grooved portion having a plurality of parallel grooves formed therein such that each of the plurality of grooves receives one of the plurality of filaments extending from the filamentary coil to produce a parallel array of filaments. A support, extending from the base-plate, and optionally integrally formed therewith, includes an outer edge and a grooved area including a plurality of grooves axially aligned with the plurality of parallel grooves of the grooved portion of the base-plate to maintain alignment of each of the plurality of filaments in the parallel array of filaments. After placement in the grooved area and the grooved portion, the filaments become set in a parallel array by application of a clamp cover over the substantially rectangular base-plate and the support. The clamp cover has a pair of holes to receive screws sized to mate with the threaded holes in the base-plate to secure the clamp cover to the clamp base. This maintains alignment of the filaments in the parallel array. The filaments extend from the filamentary coil to provide equal lengths of filaments protruding beyond the outer edge of the support.

After assembly, an apparatus according to the present invention includes a stack of frame carriers having gaps in the interfaces between divider walls through which filament ends protrude. Using optical fibers as preferred filaments, bare termini of optical fibers protrude from end portions of optical fibers that have a buffer coat on the optical fiber surface. Upon close inspection, the gaps between divider walls appear as lines of cylindrical cavities each containing the end portion of an optical fiber. A cylindrical cavity provides a shield around an optical fiber without touching the surface of the optical fiber. The shielding effect of a cylindrical cavity provides a mask to deposition of condensable material during coating by vapor deposition. A distinguishing feature of the present invention is the use of the shielding, masking effect of the cylindrical cavity to control application of material to the end portion of the optical fiber. As long as a buffered portion of an optical fiber lies inside a cylindrical cavity it should be substantially free from contact by condensable vapor, which cannot penetrate far into the cylindrical cavity at the front side of the divider walls. Adjustment of the length of bare optical fibers, extending from filament positioning frames, determines the amount of each that will protrude from the cylindrical cavities for coating using vapor deposition techniques such as ion beam sputtering, vacuum sputtering or evaporation deposition preferably ion assisted evaporation deposition.

The apparatus used for organizing filaments, according to the present invention, satisfies a number of requirements related to the placement of substantially uncontaminated material, including metal and antireflective coatings of e.g. an oxide, organic coatings, or other condensable material, on bare terminal portions of filaments, preferably optical fibers, to provide filaments or optical fibers having coated tips. Use of the apparatus provides masked filament ends for control of material deposition, as discussed above, as well as providing a convenient unit for containment and protection of filaments during shipping to and from different processing locations. After assembly, the apparatus provides a portable unit as a “plug-in” unit for suitable attachment to a vapor deposition coater. This places rows of filament tips inside a vapor deposition chamber for controlled application of material around exposed filament tips, particularly on the end faces of filament tips.

Definitions

For clarification, the following definitions provide the meaning of terms that may be used throughout this specification.

The term “filament” refers thread-like structures preferably glass structures, particularly optical fibers.

Use of the terms “coating” or “deposit” herein refers to application of selected materials, including metals, oxides and organic materials, to filament surfaces using any of a variety of methods of application, preferably vacuum coating or deposition. Coatings and deposits include known materials that provide antireflective coatings.

An “organizing fixture” may include one or more “frame carriers” that provide suitable structures for coupling to a number of “filament-positioning frames.” An apparatus according to the present invention includes an organizing fixture and a stack of frame carriers.

The beneficial effects described above apply generally to the exemplary devices and mechanisms disclosed herein of an apparatus for organizing filaments, particularly optical fibers. The specific structures through which these benefits are delivered will be described in detail hereinbelow.

### BRIEF DESCRIPTION OF THE DRAWINGS

The invention will now be described in greater detail in the following way of example only and with reference to the attached drawings in which:

FIG. 1 is a perspective view representative of a filament-positioning frame, for holding filaments in a prescribed spatial relationship.

FIG. 2 is an exploded perspective view to provide detail of components used to hold a filament coil and a parallel array of filaments.

FIG. 3 is a perspective view of an organizing fixture for a plurality of filament-positioning frames showing a single frame prepared for attachment to the fixture.

FIG. 4 is an end view showing a clamp base secured by a restraining bracket to a frame carrier to position parallel filaments in a row of V-grooves.

FIG. 5 provides perspective view to illustrate attachment of several filament-positioning frames to an organizing fixture.

FIG. 6 shows a perspective view of an organizing fixture filled to capacity with filament-positioning frames according to the present invention.

FIG. 7 is a perspective view of a portion of a organizing fixture showing a number of filament positioning frames attached to rear faces of frame carriers.

FIG. 8 provides cross-sectional view to illustrate positioning of a filament in the junction between two divider walls.

FIG. 9 is an end view showing detail of a deposition gap including cylindrical cavities each containing a bare terminal portion of a filament.

### DETAILED DESCRIPTION OF THE PREFERRED EMBODIMENTS

As required, detailed embodiments of the present invention are disclosed herein; however, it is to be understood that the disclosed embodiments are merely exemplary of the invention that may be embodied in various and alternative forms. The figures are not necessarily to scale, some features may be exaggerated or minimized to show details of particular components. Therefore, specific structural and functional details disclosed herein are not to be interpreted as limiting, but merely as a basis for the claims and as a representative basis for teaching one skilled in the art to variously employ the present invention.

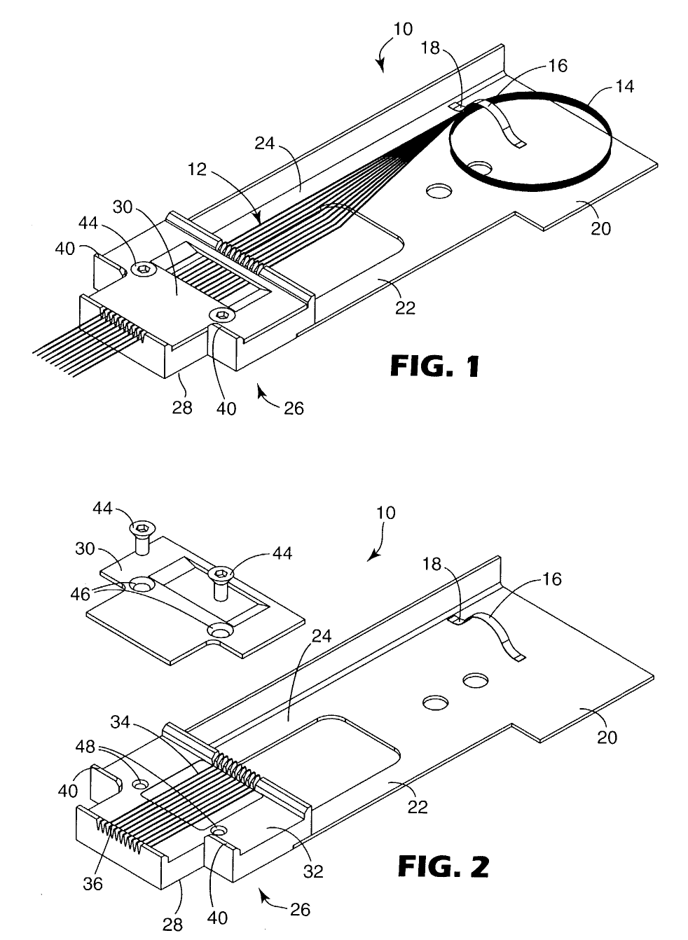

Referring now to the figures wherein like numbers identify like parts throughout the several views, FIG. 1 provides a schematic perspective view of an apparatus also referred to herein as a filament-positioning frame 10 according to the present invention. The filament-positioning frame 10 provides a means for organizing a plurality of filaments 12 preferably in the form of optical fibers. Each of the filaments 12 extends from a coil of filaments 14 conveniently retained by a clasp 16. As indicated in FIG. 1, the filament-positioning frame 10 accommodates more than a single filament 12 extending from a group of filaments 12 formed into a single coil 14. The clasp 16 may be secured using a fastener end 18 to attach it to the coil carrier 20 of the filament-positioning frame 10. A first longitudinal frame member 22 and a second longitudinal frame member 24 are parts of the coil carrier 20, which extend in a parallel, spaced-apart relationship from each other. A clamp base 26, attached to the coil carrier 20, provides coupling of longitudinal frame members 22, 24 so that they maintain their parallel relationship. A clamp cover 30 engages the clamp base 26 to capture the filaments 12 therebetween, to hold them in a prescribed spatial relationship relative to each other. Illustration of a plurality of filaments 12 shows the relationship of this parallel array to the first and second frame members 22, 24 and the extension of the ends of the filaments 12 beyond the clamp base 26. Preferably equal lengths of filaments 12 extend from a clamp base 26.

FIG. 2 shows an exploded perspective view of a filament-positioning frame 10 according to the present invention to clarify the construction and attachment of the clasp 16. As shown, the clasp 16 attaches to the coil carrier 20 by the fastener end 18. This structure is not to be viewed as limiting since it is conceivable to use other means for retaining a filamentary coil 14 against a coil carrier 20. The view of FIG. 2 omits the filaments 12 to show the structure of the clamp base 26 that includes a support 28 and a base-plate 32 each of which contribute to the positioning of the plurality of filaments 12 extending from the filamentary coil 14. Formation of a parallel array from the plurality of filaments 12 requires that the filaments 12 each occupy a groove in a portion 34 of the base-plate 32 and a groove in an area 36 of the support 28 that is in coaxial alignment with the groove in the base-plate portion 34. After positioning of filaments 12 in the grooves of the clamp base 26 the filaments 12 may be gripped in parallel array between the clamp base 26 and the clamp cover 30. For this purpose, the base-plate 32 includes alignment projections 40 to aid in accurate positioning of the clamp cover 30 with the clamp base 26. A clamp cover 30 may include alignment notches to further aid orientation of the base-plate 32 relative to the clamp base 26. Using the embodiment of the present invention illustrated in FIG. 2 the clamp cover 30 may be connected to the clamp base 26 using a pair of threaded bolts 44 inserted through a pair of holes 46 for insertion and securing in a pair of threaded receiving channels 48 formed in the base-plate 32.

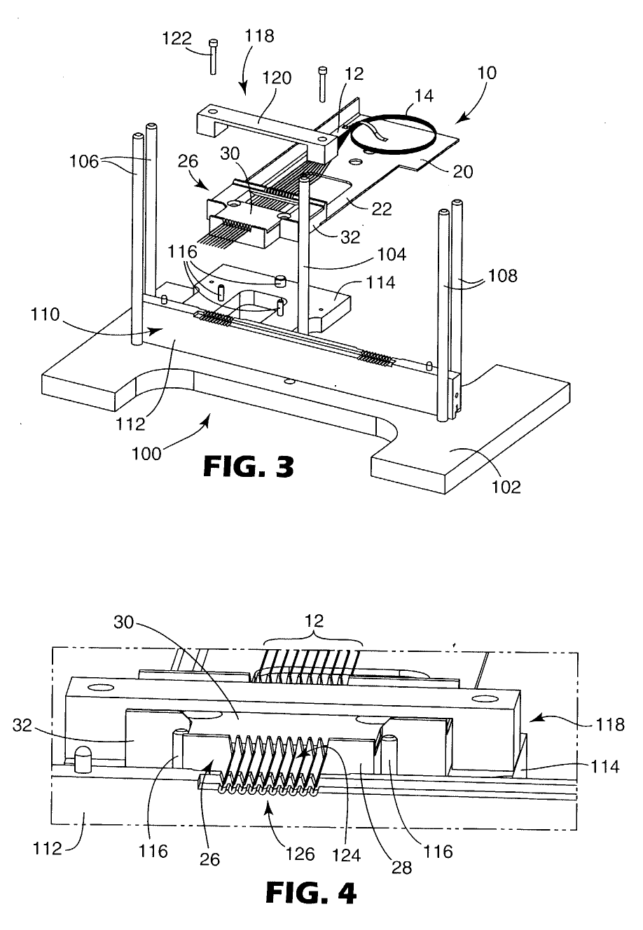

FIG. 3 provides a perspective view of a organizing fixture 100 that includes a fixture base 102 including a central rod 104, a first pair of positioning rods 106, and a second pair of positioning rods 108 spaced apart from the first pair of positioning rods 106. The central rod 104, the first pair of positioning rods 106 and the second pair of positioning rods 108 occupy positions to receive a frame carrier 110 that includes a divider wall 112 joined to at least one reference plate 114. Each reference plate 114 has pin locators 116 for precise positioning of a filament-positioning frame 10 with respect to a divider wall 112. Precise positioning of a filament-positioning frame 10 requires accurate mating of pin locators 116 against the base-plate 32 of a clamp base 26 (see FIG. 4). After correctly locating a filament-positioning frame 10 against a reference plate 114, a restraining bracket 118 may be used as a means to secure the clamp base 26 and the attached coil carrier 20 to a reference plate 114 and adjacent to a divider wall 112. FIG. 3 illustrates a restraining bracket 118 as a square brace 120 using threaded fasteners 122 as a means for securing the bracket to a reference plate 114. Other securing means may be used without departing from the scope of this invention.

FIG. 4 provides a detailed view of a clamp base 26 secured by the restraining bracket 118 to a reference base 114 showing the pin locators 116 that provide correct positioning of the support 28 so that the parallel array of filaments 12 slip into a row of V-grooves 124 formed in a portion of an edge of a divider wall 112. The filament array passes over the v-grooves 124 to extend into a line of troughs 126 that provide a semi-cylindrical wall around each of the parallel array of filaments 12 without contact occurring between the wall of each trough 126 and the surface of each filament 12.

One embodiment of the present invention includes a preferred filament as an optical fiber having a bare terminal portion protruding from an end portion of an optical fiber that is otherwise protected by at least one buffer coat. With preferred positioning, bare termini of optical fibers extend outside the boundary of a line of troughs 126 in such a way that buffer covered optical fiber end portions reside between the row of V-grooves 124 and the boundary of the line of troughs 126.

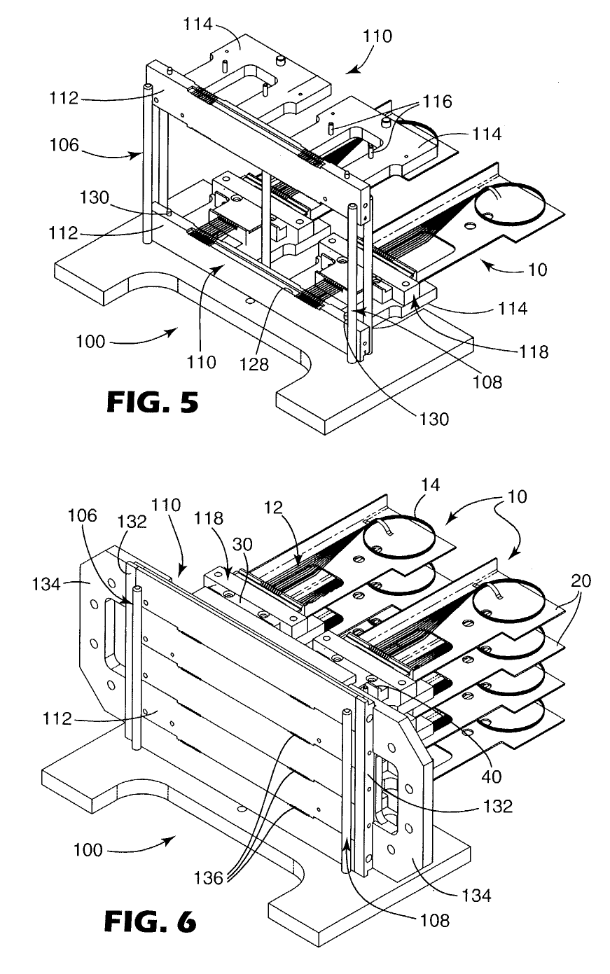

FIG. 5 shows how a second layer of filament positioning frames 10 may be added to a organizing fixture 100. For this purpose a second frame carrier 110 is added by inserting the ends of the divider wall 112 so that it is held between the first pair of positioning rods 106 and the second pair of positioning rods 108. In this position the divider wall 112 may be lowered between the positioning rods 106,108 until it rests against the upper edge 128 of the divider wall 112 used to connect the first layer of filament positioning frames 10 to the fixture base 102. Alignment pins 130, on the upper edge of the first divider wall 112, mate with indents (not shown) on the lower edge of the second divider wall 112 to guide the second layer of frame carriers 110 into a required positional relationship with the first layer of carriers 110. This places the reference plates 114 adjacent the restraining brackets 118 that hold the first layer of filament-positioning frames 10 to frame carriers 110 that were initially installed in the organizing fixture 100. Additional filament-positioning frames 10 may subsequently be located on reference plates 114 adjacent to the divider wall 112 using pin locators 116 as described above. Restraining brackets 118 provide means, as before, for securing each filament-positioning frame 10 to appropriate reference plates 114. A stack of frame carriers 110 forms by joining a number of divider walls 112 together using mating engagement of alignment pins 130, on the upper edge of each divider wall 112, with indents on the lower edge of each divider wall 112.

FIG. 6 is a perspective view illustrating the result of increasing the number of frame carriers 110 to increase the number of filament positioning frames 10 included in a organizing fixture 100. Two filament positioning frames 10 are loaded in each frame carrier 110 and there are preferably four layers. The resulting structure includes a number of divider walls 112 having a combined height similar to the height of the pairs of positioning rods 106,108. Although the positioning rods 106,108 provide some support, it is preferable to unify the structure of a organizing fixture 100 using a bracing strip 132 connected to each divider wall 112 in the stack. Flanges 134 attached to each bracing strip 132 provide a means for attaching a organizing fixture 100 to a vapor deposition unit for application of condensable material at the termini of the filaments 12 exposed in deposition gaps 136 between each layer of a stack of divider walls 112.

Vapor deposition of material according to the present invention, using either evaporation or sputtering techniques, deposits material substantially on the end faces of exposed tips of optical fibers. As mentioned previously, a preferred process for depositing material on the end faces of optical fibers uses equipment of the type described in U.S. Pat. No. 5,849,162. The process uses reactive sputtering after attaching an organizing fixture 100 to vapor deposition equipment. This places bare terminal portions of optical fibers inside a reduced pressure chamber, typically having a circular cross-section, operating between 10⁻⁴ torr and 10⁻² torr. The vapor deposition equipment includes means for transporting the terminal portions of optical fibers, past one or more coating stations. A gap between about 25 mm and about 75 mm separates the optical fiber tips from the vapor deposition source during coating by sputtering at reduced pressure of about 5×10⁻³ torr. The chamber of circular cross section rotates past one or more coating stations comprising a magnetron sputtering device and an elongated plasma generator. During deposition of material, the plasma generated by the sputtering target and the plasma generator interdiffuse so as to form one continuous activating and sputtering plasma. For this purpose, the sputtering target and elongated plasma generator occupy positions that are spatially and atmospherically contiguous. Equipment of the type described previously may be used to deposit multiple layers of material by movement of bare optical fiber termini through coating zones past sputtering targets of differing chemical composition.

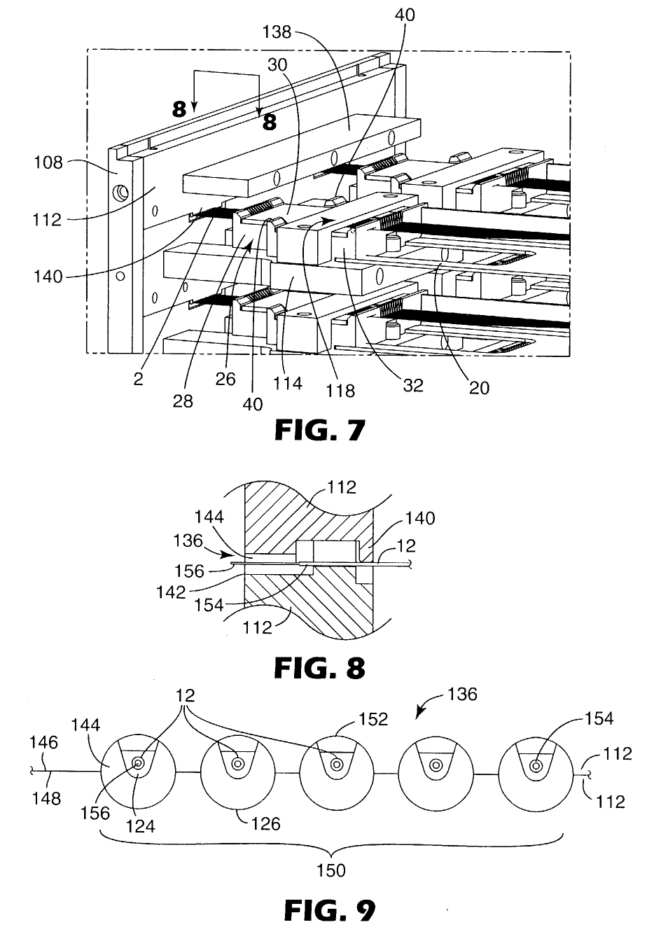

FIG. 7 provides a perspective view of the rear faces of a stack of divider walls 112 providing detail of the relative positioning of base clamps 26 with reference plates 114 and coil carriers 20. The rear face of each divider wall 112 has one or more filament alignment bars 140 attached to, or formed in, a divider wall 112 to apply pressure to an array of filaments 12 so that each filament settles towards the bottom of a V-groove without sustaining any damage such as filament crimping. A protector plate 138 protects the uppermost array of filaments 12 from inadvertent contact.

FIG. 8 is a cross sectional view taken through line 8-8 of FIG. 7 to show the stricture inside a deposition gap 136 and the relative positioning of a buffered portion 154 of a filament 12, in the form of an optical fiber, and a bare terminal portion 156 requiring application of condensable material using vapor deposition equipment. In a preferred position, the front entry 142 of the cylindrical cavity 144, surrounding an optical fiber 12, acts as a mask to prevent deposition of condensable material inside the cylindrical cavity 144. With this arrangement deposition from oblique angles is masked by the front entry 142. After completion of the vacuum deposition process, substantially only the bare end face of each optical fiber 12, in an array of optical fibers 12, becomes coated. This leaves the terminal shank and buffer coated portion of the optical fiber 154, inside the cylindrical cavity 144, substantially free from deposited material.

FIG. 9 is an end view showing detail of a deposition gap 136 formed around a parallel array of optical fibers 12, located between the lower edge 146 of one divider wall 112 and the upper edge 148 of an underlying divider wall 112. On close inspection, a deposition gap 136 appears as a line of circular openings 150 each of which is actually a cylindrical cavity 144 formed by a semi-cylindrical trough 126 in the underlying divider wall 112 and a semi-cylindrical conduit 152 formed in the lower edge 146 of an overlying divider wall 112. FIG. 9 also illustrates the positioning of optical fibers 12 in V-grooves 124 with a buffered portion 154 in contact with the walls of a V-groove 124 leaving the bare terminal portion of each optical fiber 156 in a spaced apart relationship from any nearby surface.

Vapor deposition of material according to the present invention significantly limits deposition of material on the buffer surface normal to the deposition source during physical vapor deposition using either electron beam or sputtering techniques. The combination of a cylindrical cavity 144 around an optical fiber 12 and withdrawal, into the cavity 144, of the boundary between the bare fiber 156 and the buffered portion 154 of each optical fiber 12, substantially masks the buffered portion 154 from most non-normal vacuum deposition of coating material.

The design of a organizing fixture 100 according to the present invention prevents damage both to lenses formed on the end of optical fibers and to exposed cladding around an optical fiber core. This results from the use of alignment bars 140, that provide vertical positioning of an array of optical fibers 12, and deep V-grooves 124 machined for horizontal positioning and separation between optical fibers 12. Correct vertical and horizontal positioning of a parallel array of optical fibers 12 according to the present invention prevents crimping of any of the optical fibers 12 during assembly of a organizing fixture 100. Damage by crimping or breaking occurs with other types of filament organizers that use concentric half-cylinders only slightly larger than the buffer diameter for alignment of optical fibers. The tendency toward crimping or filament breakage occurs when a filament is not straight or strays outside the bottom half-cylinder during loading of an array of filaments. Outside of the bottom half-cylinder, filaments lack protection from entrapment and damage between containment structures for subsequently applied layers of filaments. In contrast, the present invention safely places filaments 12, preferably optical fibers, in V-grooves 124 and semi-cylindrical troughs 126 before formation of cylindrical cavities 144 around them during application of subsequent layers of frame carriers 110. Filaments 12 placed in cylindrical cavities 150 in this way are free from the risk of damage to lens tipped optical fibers that occurs when threading fiber tips through cylindrical shafts in such a way to cause damage to the lensed ends of optical fibers.

A filament organizing apparatus according to the present invention facilitates a batch process for controlled application of a material, such as anti-reflective metal oxides and organic compounds, vapor deposited at reduced pressure to the end faces of optical fibers. A distinguishing feature of an organizing fixture 100 according to the present invention is the ease with which it may be incorporated into a vacuum deposition process to deposit a layer of metal, oxide or organic compound substantially on the end face of a bare optical fiber portion 156 of each of a plurality of optical fibers 12. The end face of a bare tip of a terminal portion of an optical fiber may be either a planar surface or may include a lens structure. The end surfaces may receive a deposit of an opaque or transparent material. Deposit of transparent material on the planar end face or optical fiber lens, according to the present invention, provides a highly transparent layer so that there is minimum attenuation of light passing between coated ends of a pair of optical fibers connected together in an optical fiber network or optoelectronic device. A preferred anti-reflective coating sputtered on the end face of an optical fiber comprises alternating layers of metal oxides. The first layer, in contact with the optical fiber end face, includes tantalum pentoxide. Subsequent layers include, silicon dioxide, a second deposit of tantalum pentoxide and an exterior layer of silicon dioxide. There is evidence to show that antireflective coatings from about 0.4 μm to about 1.2 μm thick exhibit reflectance less than about 0.3% depending upon the thickness of the individual layers deposited and the number of layers.

Restriction of anti-reflective coating to substantially only the end face of a stripped end portion of an optical fiber depends upon the dimensions of the shielding, masking cavity, preferably a cylindrical cavity, compared to the diameter of a clad optical fiber. A clad optical fiber, having a diameter typically less than 125 μm was shielded by a variety of cylindrical cavities formed around optical fibers that were each withdrawn inside their respective cavities to cover the boundary between the clad optical fiber and the buffered portion that had a diameter of about 250 μm. Withdrawal of the boundary into the cavity substantially masks the buffered portion from most non-normal vacuum deposition of coating material particularly for cavities having aspect ratios from about 1:1 to about 1:4, preferably about 1:2 to about 1:4. As used herein the term aspect ratio refers to the relative difference in sizing of the opening of a cylindrical cavity in comparison to its length. Using normal gaps of between about 25 mm and 75 mm between sputtering sources and fixtures according to the present invention, very little material enters a cavity that has an opening of 1.0 mm or less. Using a cavity of 1.0 mm diameter there was evidence of material deposit on the sidewalls inside the cavity up to 1.0 mm from the entry of the cavity. As the diameter of the opening and cavity increased there was more evidence of material deposit on the cavity sidewalls near to the entry. The length dimension, corresponding to the depth of a cavity, had a maximum value of 4 mm. Optimum cavity shielding of terminal portions of optical fibers was observed when the diameter of a cavity opening was between about 1.5 mm and 2 mm. Cavity openings in this range provide enough space between the cavity sidewalls and optical fibers to avoid potentially damaging contact between them. A preferred cavity diameter of 1.5 mm allows optical fibers to be distributed on 2 mm centers.

Attachment of a filament organizing fixture 100 to vapor deposition equipment may use any suitable connection means that will hold the fixture 100 in place during normal operation of the coating equipment. When the coating equipment provides deposition of coating material, as in vapor deposition, an attachment port is typically available to receive the fixture 100. Contact between the port and the fixture 100 may be maintained using a connecting flange 134 (see FIG. 6) or other compatible connecting structure.

A filament organizing apparatus and its component parts, for facilitating the coating particularly of end faces of filament tips, have been described herein. These devices and related variations, which will be appreciated by those skilled in the art, are within the intended scope of this invention as claimed below. As previously stated, detailed embodiments of the present invention are disclosed herein; however, it is to be understood that the disclosed embodiments are merely exemplary of the invention that may be embodied in a variety of forms.

What is claimed is:

1. A filament positioning frame for a filamentary coil and a plurality of filaments extending therefrom, said filament positioning frame comprising:
a coil carrier including an elongate plate having a first end opposite a second end;
a coil retainer attached to said coil carrier at said first end, said coil retainer including a fastener end to attach said coil retainer to said coil carrier, said coil retainer further including a clasp end to restrict movement of the filamentary coil at said first end of said coil carrier;
a clamp base attached at said second end of said coil carrier, said clamp base including a substantially rectangular base-plate having a lower surface and an upper surface, said lower surface being in contact with said coil carrier, said base-plate including alignment projections at said upper surface, said base-plate further including a grooved portion having a plurality of parallel grooves formed therein such that each of said plurality of grooves receives one of the plurality of filaments extending from the filamentary coil to produce a parallel array of filaments;
a support extending from said base-plate, said support including an outer edge and a grooved area including a plurality of grooves axially aligned with said plurality of parallel grooves of said grooved portion of said base-plate to maintain alignment of each of the plurality of filaments in the parallel array of filaments; and
a clamp cover sized to mate with said clamp base to maintain alignment of the plurality of filaments in the parallel array, the plurality of filaments extending from the filamentary coil such that each has a length to protrude equally beyond said outer edge of said support.

2. The filament positioning frame of claim 1, wherein said rectangular base-plate has a pair of threaded holes formed therein, opening to said upper surface.

3. The filament positioning frame of claim 2, wherein said clamp cover has a pair of holes formed therein to receive screws sized to mate with said threaded holes in said rectangular base-plate to secure said clamp cover to said clamp base.

4. The filament positioning frame of claim 1, wherein said support is integrally formed with said rectangular base-plate.

5. An optical fiber positioning frame for an optical fiber coil and a plurality of optical fibers extending therefrom, said optical fiber positioning frame comprising:
a coil carrier including an elongate plate having a first end opposite a second end;
a coil retainer attached to said coil carrier at said first end, said coil retainer including a fastener end to attach said coil retainer to said coil carrier, said coil retainer further including a clasp end to restrict movement of the optical fiber coil at said first end of said coil carrier;
a clamp base attached at said second end of said coil carrier, said clamp base including a substantially rectangular base-plate having a lower surface and an upper surface, said lower surface being in contact with said coil carrier, said base-plate including alignment projections at said upper surface and having a pair of threaded holes formed therein, said base-plate further including a grooved portion having a plurality of parallel grooves formed therein such that each of said plurality of grooves receives one of the plurality of optical fibers extending from the optical fiber coil to produce a parallel array of optical fibers;
a support extending from said base-plate, said support including an outer edge and a grooved area including a plurality of grooves axially aligned with said plurality of parallel grooves of said grooved portion of said base-plate to maintain alignment of each of the plurality of optical fibers in the parallel array of optical fibers; and
a clamp cover shaped to cover said substantially rectangular base-plate and said support, said clamp cover having a pair of holes formed therein to receive screws sized to mate with said threaded holes in said base-plate to secure said clamp cover to said clamp base to maintain alignment of the plurality of optical fibers in the parallel array of optical fibers, the plurality of optical fibers extending from the optical fiber coil such that each has a length to protrude equally beyond said outer edge of said support.

6. An apparatus for positioning a plurality of filament termini for controlled deposition of condensable vapors, said apparatus comprising:
an organizing fixture including a fixture base;
at least a first frame carrier including a divider wall having an upper edge opposite a lower edge, said lower edge having contact with said fixture base;
at least one reference plate attached to said divider wall of said at least a first frame carrier;
at least one filament positioning frame, connected to said at least one reference plate, said at least one filament positioning frame comprising:
a coil carrier;
a coil retainer attached to said coil carrier to restrict movement of a filamentary coil held to said coil carrier by said coil retainer;
a clamp base attached to said coil carrier opposite said coil retainer, said clamp base including a lower surface in contact with said coil carrier, said clamp base including alignment projections at an upper surface thereof, said clamp base including a grooved portion having a plurality of parallel grooves formed therein such that each of said plurality of grooves receives one of a plurality of filaments extending from the filamentary coil to produce a parallel array of filaments, said clamp base further including a support having an outer edge and a grooved area including a plurality of grooves axially aligned with said plurality of parallel grooves of said grooved portion of said clamp base to maintain alignment of each of the plurality of filaments in the parallel array of filaments; and
a clamp cover engageable with said clamp base to secure said clamp cover to said clamp base to maintain alignment of the plurality of filaments in the parallel array, the plurality of filaments extending from the filamentary coil such that each has a length to protrude equally beyond said outer edge of said support;
a row of grooves formed in said upper edge of said divider wall of said at least a first frame carrier;
at least a second frame carrier including a divider wall having an upper edge opposite a lower edge that contacts said upper edge of said divider wall of said at least a first frame carrier;
at least one reference plate attached to said divider wall of said at least a second frame carrier;
at least one filament-positioning frame, connected to said at least a second frame carrier, said at least one filament positioning frame comprising:
a coil carrier;
a coil retainer attached to said coil carrier to restrict movement of a filamentary coil held to said coil carrier by said coil retainer;
a clamp base attached to said coil carrier opposite said coil retainer, said clamp base including a lower surface in contact with said coil carrier, said clamp base including alignment projections at an upper surface thereof, said clamp base including a grooved portion having a plurality of parallel grooves formed therein such that each of said plurality of grooves receives one of a plurality of filaments extending from the filamentary coil to produce a parallel array of filaments, said clamp base further including a support having an outer edge and a grooved area including a plurality of grooves axially aligned with said plurality of parallel grooves of said grooved portion of said clamp base to maintain alignment of each of the plurality of filaments in the parallel array of filaments; and
a clamp cover engageable with said clamp base to secure said clamp cover to said clamp base to maintain alignment of the plurality of filaments in the parallel array, the plurality of filaments extending from the filamentary coil such that each has a length to protrude equally beyond said outer edge of said support;
a row of grooves formed in said upper edge of said divider wall of said at least a second frame carrier;
an alignment bar, attached to said lower edge of said divider wall of said at least a second frame carrier to apply pressure to the plurality of filaments in the parallel array of filaments of said at least a first frame carrier such that the plurality of filaments of the parallel array of filaments occupy a common plane in which the plurality of filaments protrude from a plurality of cylindrical cavities formed at an interfacial portion between said lower edge of said divider wall of said at least a second frame carrier and said upper edge of said divider wall of said at least a first frame carrier to expose the plurality of filament termini to condensable vapors for material deposition thereupon.

7. A filament organizing apparatus for use with vacuum deposition coating equipment, said filament organizing apparatus comprising:
a faceplate including at least a first divider wall having placed thereon at least a second divider wall to provide an interface between said at least a first divider wall and said at least a second divider wall, said interface including a plurality of openings in a common plane, each of said plurality of openings having an entry into a cavity, formed between said at least a first divider wall and said at least a second divider wall, said cavity occupied by an optical fiber having coaxial alignment therewith, the optical fiber including a boundary between a bare terminal portion and a buffered portion of the optical fiber, the boundary positioned in said cavity to allow a section of the bare terminal portion to protrude from said entry in front of said faceplate for deposition of condensable material thereon, said entry of each of said plurality of openings having a size to substantially prevent deposit of condensable material from reaching the boundary inside said cavity.

8. The filament organizing apparatus of claim 7, wherein said cavity has a depth providing an aspect ratio of said size of said entry to said depth from about 1:1 to about 1:4.

9. The filament organizing apparatus of claim 8, wherein said aspect ratio is about 1:2.

10. The filament organizing apparatus of claim 7, wherein said size of said entry is from about 1.0 mm to about 2.0 mm, preferably about 1.5 mm.

11. The filament organizing apparatus of claim 7, wherein said section of the bare terminal portion is limited substantially to the end face thereof.

12. An apparatus for positioning a plurality of filament termini for controlled deposition of condensable vapors, said apparatus comprising:
an organizing fixture including a fixture base having a central rod between a first pair of positioning rods and a second pair of positioning rods;
at least a first frame carrier including a divider wall having a first end opposite a second end, a front side opposite a rear side and an upper edge opposite a lower edge, said first end sized to fit between said first pair of positioning rods, and said second end sized to fit between said second pair of positioning rods such that a portion of said divider wall, between said first end and said second end, lies adjacent to said central rod, said lower edge having contact with said fixture base;
at least one reference plate attached to said divider wall of said at least a first frame carrier, said at least one reference plate having a plurality of pin locators projecting therefrom;
at least one filament positioning frame connected to said at least a first frame carrier, said at least one filament positioning frame comprising:
a coil carrier including an elongate plate having a first end opposite a second end;
a coil retainer attached to said coil carrier at said first end, said coil retainer including a fastener end to attach said coil retainer to said coil carrier, said coil retainer further including a clasp end to restrict movement of a filamentary coil at said first end of said coil carrier;
a clamp base attached at said second end of said coil carrier, said clamp base including a substantially rectangular base-plate having an upper surface and a lower surface including a plurality of receiving holes to receive said plurality of pin locators projecting from said reference plate, said lower surface being in contact with said coil carrier, said base-plate including alignment projections at each corner of said upper surface and having a pair of threaded holes formed therein, said base-plate further including a grooved portion having a plurality of parallel grooves formed therein such that each of said plurality of grooves receives one of a plurality of filaments extending from the filamentary coil to produce a parallel array of filaments;
a support extending from said base-plate, said support including an outer edge and a grooved area including a plurality of grooves axially aligned with said plurality of parallel grooves of said grooved portion of said base-plate to maintain alignment of each of the plurality of filaments in the parallel array of filaments; and
a clamp cover shaped to cover said substantially rectangular base-plate and said support, said clamp cover having a pair of holes formed therein to receive screws sized to mate with said threaded holes in said base-plate to secure said clamp cover to said clamp base to maintain alignment of the plurality of filaments in the parallel array, the plurality of filaments extending from the filamentary coil such that each has a length to protrude equally beyond said outer edge of said support;
a restraining bracket sized for placement over said clamp base, said restraining bracket having opposing ends each including an opening to receive a threaded bolt to secure said restraining bracket and said clamp base to said reference plate;
a row of grooves formed in said upper edge of said divider wall of said at least a first frame carrier, each of said row of grooves including a V-groove portion to receive one of the plurality of filaments of the parallel array, each of said row of grooves further including a semi-cylindrical section opening to said front side of said divider wall of said at least a first frame carrier;
at least a second frame carrier including a divider wall having a first end opposite a second end, a front side opposite a rear side and an upper edge opposite a lower edge, said first end sized to fit between said first pair of positioning rods, and said second end sized to fit between said second pair of positioning rods such that a portion of said divider wall, between said first end and said second end, lies adjacent to said central rod, said lower edge having contact with said upper edge of said divider wall of said at least a first frame carrier, said lower edge further including a plurality of axially parallel semicylindrical channels;
at least one reference plate attached to said divider wall of said at least a second frame carrier, said at least one reference plate having a plurality of pin locators projecting therefrom;
at least one filament positioning frame, connected to said at least a second frame carrier, said at least one filament positioning frame comprising:
a coil carrier including an elongate plate having a first end opposite a second end;
a coil retainer attached to said coil carrier at said first end, said coil retainer including a fastener end to attach said coil retainer to said coil carrier, said coil retainer further including a clasp end to restrict movement of a filamentary coil at said first end of said coil carrier;
a clamp base attached at said second end of said coil carrier, said clamp base including a substantially rectangular base-plate having an upper surface and a lower surface including a plurality of receiving holes to receive said plurality of pin locators projecting from said reference plate, said lower surface being in contact with said coil carrier, said base-plate including alignment projections at each corner of said upper surface and having a pair of threaded holes formed therein, said base-plate further including a grooved portion having a plurality of parallel grooves formed therein such that each of said plurality of grooves receives one of a plurality of filaments extending from the filamentary coil to produce a parallel array of filaments;
a support extending from said base-plate, said support including an outer edge and a grooved area including a plurality of grooves axially aligned with said plurality of parallel grooves of said grooved portion of said base-plate to maintain alignment of each of the plurality of filaments in the parallel array of filaments; and
a clamp cover shaped to cover said substantially rectangular base-plate and said support, said clamp cover having a pair of holes formed therein to receive screws sized to mate with said threaded holes in said base-plate to secure said clamp cover to said clamp base to maintain alignment of the plurality of filaments in the parallel array, the plurality of filaments extending from the filamentary coil such that each has a length to protrude equally beyond said outer edge of said support;
a restraining bracket sized for placement over said clamp base, said restraining bracket having opposing ends each including an opening to receive a threaded bolt to secure said restraining bracket and said clamp base to said reference plate;
a row of grooves formed in said upper edge of said divider wall of said at least a second frame carrier, each of said row of grooves including a V-groove portion to receive one of the plurality of filaments of the parallel array, each of said row of grooves further including a semi-cylindrical channel opening to said front side of said divider wall of said at least a second frame carrier; and
an alignment bar, attached to said lower edge of said rear side of said divider wall of said at least a second frame carrier to apply pressure to the plurality of filaments in the parallel array of said at least one filament positioning frame connected to said at least a first frame carrier to cause abutment between said V-grooves of said row of grooves of said at least a first frame carrier such that the plurality of filaments of the parallel array occupy a common plane in which the plurality of filaments protrude from a plurality of cylindrical cavities formed by overlap of each said semi-cylindrical section of said at least a first frame carrier by a said semi-cylindrical channel of said at least a second frame carrier to provide said plurality of filament termini for exposure to condensable vapors for deposition thereupon.
